(19) United States
(12) Patent Application Publication
(10) Pub. No.: US 2016/0079783 A1
(43) Pub. Date: Mar. 17, 2016

(54) BATTERY CHARGING MODULE FOR A VEHICLE

(71) Applicant: Nissan North America, Inc., Franklin, TN (US)

(72) Inventors: Nelson PHAN, Rochester Hills, MI (US); Randall JOHNSON, White Lake, MI (US); Bhargav SURA, Sterling Heights, MI (US)

(21) Appl. No.: 14/483,820

(22) Filed: Sep. 11, 2014

(51) Int. Cl. H02J 7/00; H05K 7/20

(52) U.S. Cl. CPC H02J 7/0052; H05K 7/20218; H05K 7/2039; H02J 7/0047

(57) ABSTRACT

A battery charging assembly for a vehicle includes a vehicle battery and a charging module electrically connected to the vehicle battery and configured to supply electrical energy to the battery. An energy harvesting module is electrically connected to the charging module. The energy harvesting module is configured to harvest energy, to convert the harvested energy to electrical energy and to supply the electrical energy to the charging module. A cooling circuit supplies a cooling fluid to the energy harvesting module to cool the energy harvesting module.

### BACKGROUND

1. Field of the Invention

The present invention generally relates to a battery charging module for a vehicle. More specifically, the present invention relates to a battery charging module for a vehicle including an energy harvesting module and a cooling circuit to collect heat to trickle charge a vehicle battery.

2. Background Information

A battery of an internal combustion engine (ICE) vehicle is depleted both during operation of the vehicle and while the vehicle is idle. A depleted battery can interfere with operation of the vehicle, such as preventing the vehicle from starting. Accordingly, a need exists for an energy harvesting system for a vehicle that harvests and utilizes ambient energy to trickle charge the battery of an internal combustion engine vehicle.

### SUMMARY

In view of the state of the known technology, one aspect of the present invention includes a battery charging assembly for a vehicle including a vehicle battery and a charging module electrically connected to the vehicle battery and configured to supply electrical energy to the battery. An energy harvesting module is electrically connected to the charging module. The energy harvesting module is configured to harvest energy, to convert the harvested energy to electrical energy and to supply the electrical energy to the charging module. A cooling circuit supplies a cooling fluid to the energy harvesting module to cool the energy harvesting module.

Another aspect of the present invention includes a battery charging assembly for a vehicle including a battery and a charging module electrically connected to the battery and configured to supply electrical energy to the battery. An energy harvesting module is disposed in an engine compartment of a vehicle and electrically connected to the charging module. The energy harvesting module is configured to harvest energy, to convert the harvested energy to electrical energy and to supply the electrical energy to the charging module. The energy harvesting module includes a thermoelectric device having opposite first and second sides. A thermal pad is configured to be connected to a vehicle component. A heat sink is connected between the thermal insulation pad and the first side of the thermoelectric device. A cooling block is connected to a second side of the thermoelectric device. A cooling circuit supplies a cooling fluid to the cooling block of the energy harvesting module to cool the energy harvesting module.

Yet another aspect of the present invention includes a method of charging a vehicle battery. Heat energy is captured with an energy harvesting module. A cooling fluid is supplied to the energy harvesting module to increase a temperature difference at a thermoelectric device of the energy harvesting module. The captured heat energy is converted to electrical energy with the energy harvesting module. The converted electrical energy is stored. The stored electrical energy is supplied to the battery when the battery is less than fully charged.

### BRIEF DESCRIPTION OF THE DRAWINGS

Referring now to the attached drawings which form a part of this original disclosure:

FIG. 1 is a schematic illustration of a battery charging system for a vehicle in accordance with an exemplary embodiment of the present invention;

FIG. 2 is a schematic illustration of an energy harvesting module of the battery charging system of FIG. 1;

FIG. 3 is a plan view of the energy harvesting module of FIG. 2;

FIG. 4 is a schematic illustration of a plurality of energy harvesting modules connected in series to a charging module;

FIG. 5 is a schematic illustration of a cooling circuit connected to a cooling block of the energy harvesting module;

FIG. 6 is a schematic illustration of the cooling circuit in fluid communication with a washer fluid reservoir;

FIG. 7 is schematic illustration of a cooling circuit in fluid communication with an air conditioning system refrigerant loop of a vehicle;

FIG. 8 is a perspective view of the air conditioning system refrigerant loop of FIG. 7 with the cooling circuit in fluid communication therewith;

FIG. 9 is a perspective view of the energy harvesting module connected proximate a coolant loop of an engine in an engine compartment of a vehicle;

FIG. 10 a perspective view of the energy harvesting module connected to an exhaust system in an engine compartment of a vehicle;

FIG. 11 is a perspective view of the energy harvesting module connected proximate a heat shield of an engine block in an engine compartment of a vehicle; and

FIG. 12 is a schematic illustration and flowchart illustrating operation of the battery charging system.

### DETAILED DESCRIPTION OF EXEMPLARY EMBODIMENTS

Selected exemplary embodiments will now be explained with reference to the drawings. It will be apparent to those skilled in the art from this disclosure that the following descriptions of the exemplary embodiments are provided for illustration only and not for the purpose of limiting the invention as defined by the appended claims and their equivalents.

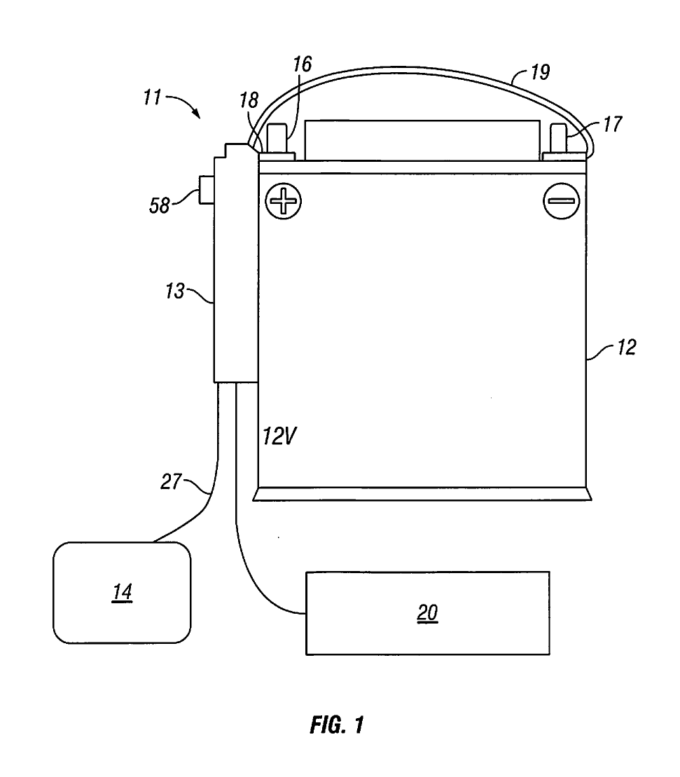

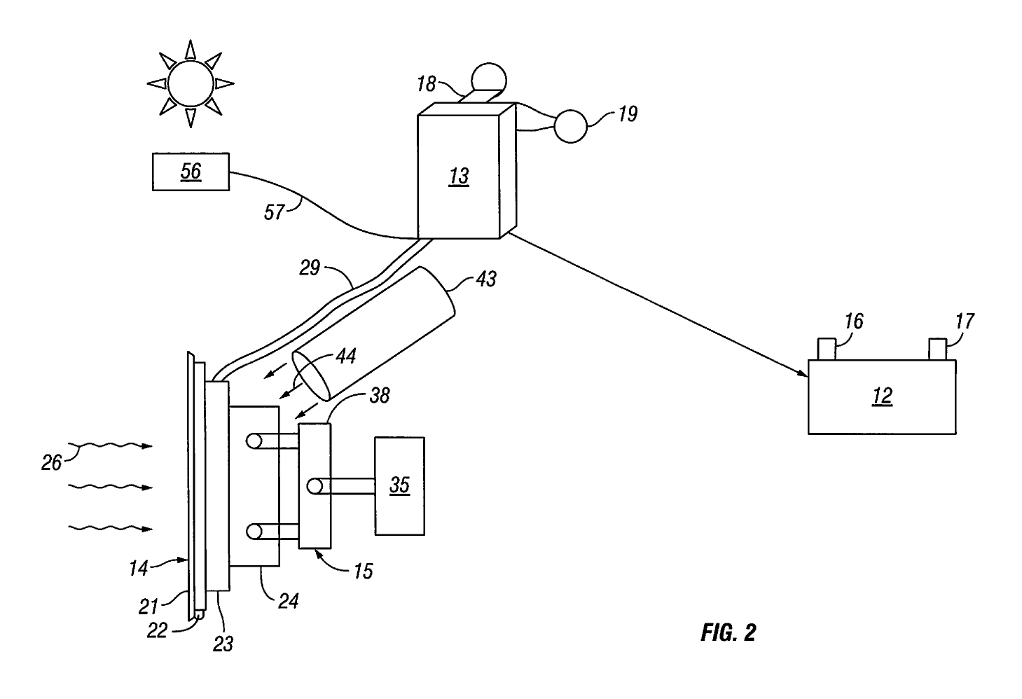

A battery charging system 11 for a vehicle includes a vehicle battery 12 and a charging module 13 electrically connected to the vehicle battery 12 and configured to supply electrical energy to the battery 12, as shown in FIGS. 1 and 2. An energy harvesting module 14 is electrically connected to the charging module 13. The energy harvesting module 14 is configured to harvest energy and to convert the harvested energy to electrical energy, which is supplied to the charging module 13. A cooling circuit 15 supplies a cooling fluid to the energy harvesting module 14 to increase a temperature differential at the energy harvesting module 14 to facilitate harvesting energy.

The battery 12 is preferably a conventional twelve (12) volt automobile battery. As shown in FIG. 1, the battery 12 has a positive terminal 16 and a negative terminal 17.

The charging module 13 is electrically connected to the battery 12 by a first wire 18 and a second wire 19. The first wire 18 is connected to the positive terminal 16 of the battery 12, and the second wire 19 is connected to the negative terminal 17. The charging module 13 is preferably mechanically connected to the battery 12 in any suitable manner, such as by a bracket, although the charging module 13 can be mounted in any suitable location. As shown in FIG. 1, the charging module 13 can include an electrical socket 20 for receiving a conventional electrical connector, such as a 110 volt plug.

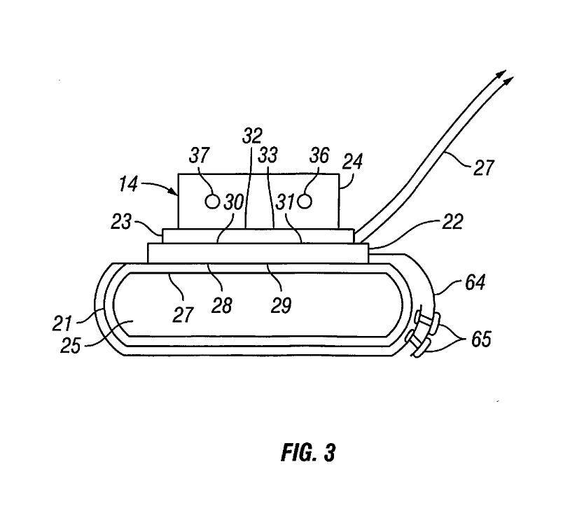

The energy harvesting module 14 includes a thermal pad 21, a heat sink 22, a thermoelectric device 23 and a cooling block 24, as shown in FIGS. 2 and 3. A wire 27 electrically connects the thermoelectric device 23 of the energy harvesting module 14 to the charging module 13. The wire 27 supplies the converted electrical energy from the energy harvesting module 14 to the charging module 13. The energy harvesting module 14 can be connected to a vehicle component 25 in any suitable manner, such as with a bracket 64. Fasteners 65 secure the bracket 64 to vehicle component 25, thereby securely mounting the energy harvesting module 14 thereto.

The thermal pad 21 is connected to a vehicle component 25 that generates heat 26, as shown in FIGS. 2 and 3. A first side 27 of the thermal pad 21 is adjacent the vehicle component 25. A second side 28 of the thermal pad 21 is adjacent a first side 29 of the heat sink 22. The thermal pad 21 provides high temperature stability and good electrical insulation properties, as well as providing high thermal conductivity. Some components in the engine compartment generate significant heat, such as the exhaust being approximately 1000° F. The thermal pad 21 thermally insulates the energy harvesting module 14 from excessive heat generated in the engine compartment. The thermal pad 21 also reduces vibration between the vehicle component 25 and the energy harvesting module 14.

The first side 29 of the heat sink 22 is disposed adjacent the second side 28 of the thermal pad, as shown in FIGS. 2 and 3. A second side 30 of the heat sink 22 is disposed adjacent a first side 31 of the thermoelectric device 23. The heat sink 22 transfers the heat energy from the thermal pad 21 to the first side 31 of the thermoelectric device 23.

The first side 31 of the thermoelectric device 23 is disposed adjacent the second side 30 of the heat sink 22, as shown in FIGS. 2 and 3. A second side 32 of the thermoelectric device 23 is disposed adjacent a first side of the cooling block 33. The first side 31 of the thermoelectric device 23 is opposite the second side 32. The thermoelectric device 23 converts a temperature difference to electric voltage.

The first side of the cooling block 24 is disposed adjacent the second side 32 of the thermoelectric device 23, as shown in FIGS. 2 and 3. The cooling block 24 is in fluid communication with a cooling circuit 15 to supply the cooling fluid to the cooling block 24. The cooling block 24 cools the second side 32 of the thermoelectric device 23, thereby creating a larger temperature difference between the first and second sides of the thermoelectric device 23. Supplying the cooling fluid to the cooling block 24 provides a constant lower temperature to the second side 32 of the thermoelectric device to increase the efficiency of the heat energy conversion.

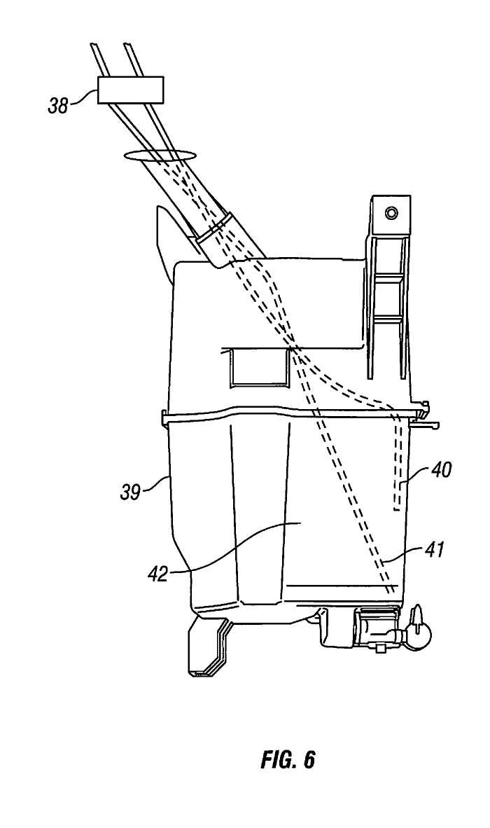

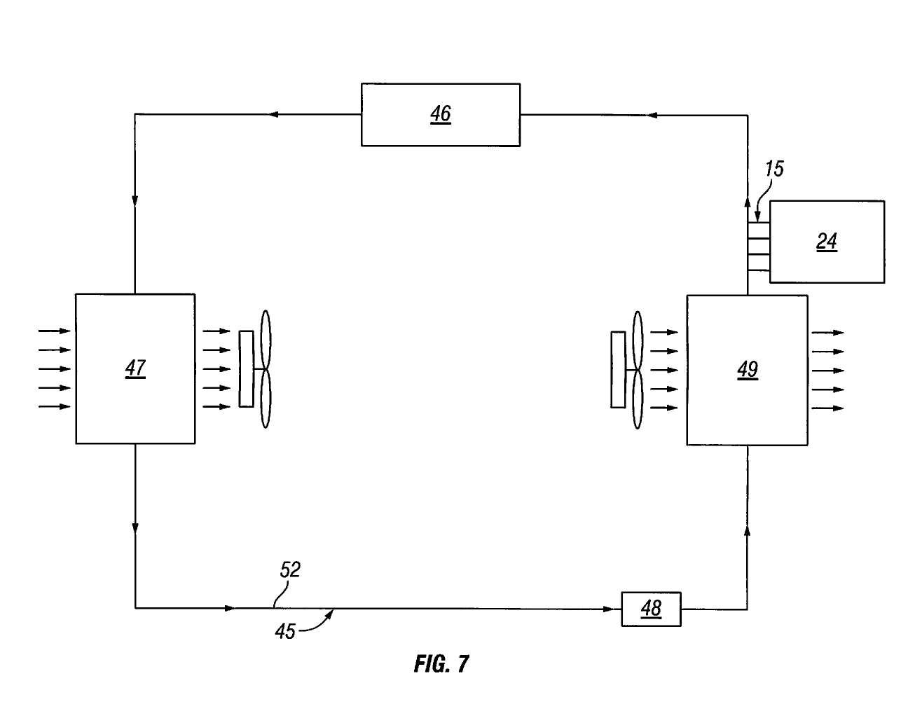

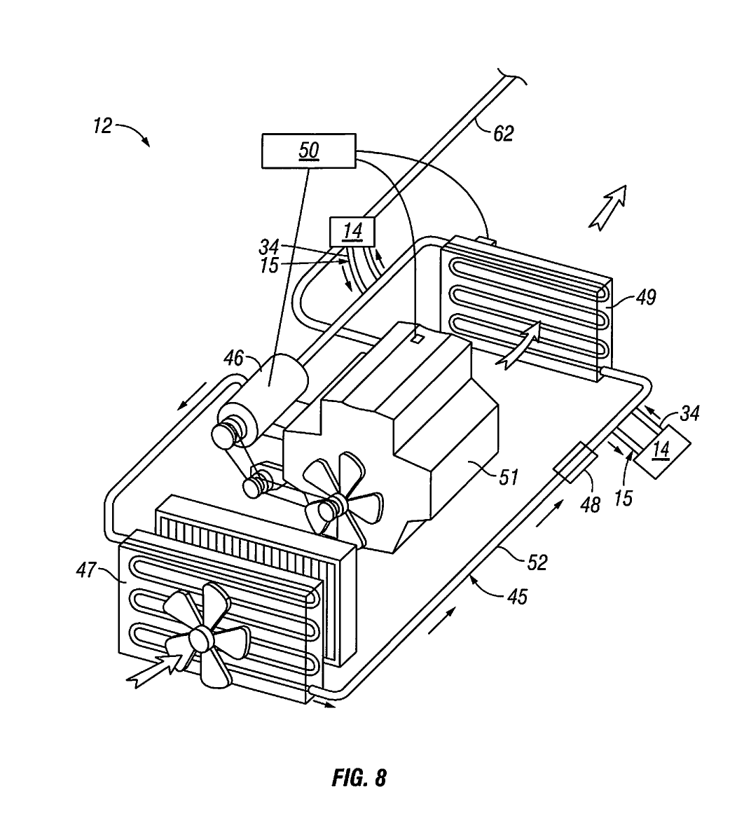

A cooling circuit 15 supplies cooling fluid from a source 35 to the cooling block 24, as shown in FIG. 2. A pump 38 can be disposed in the cooling circuit 15 to facilitate moving the cooling fluid through the cooling block 24. The cooling circuit 15 can be connected to a washer fluid reservoir 39 as shown in FIGS. 5 and 6, an air conditioning system refrigerant loop 45 as shown in FIGS. 7 and 8, or any other suitable source. A fan 43 can be mounted to further cool the cooling fluid supplied to the cooling block 43, as shown in FIGS. 2 and 5.

A first exemplary cooling circuit 15 is shown in FIGS. 5 and 6. The cooling circuit 15 includes tubing 34 that supplies a cooling fluid 42 from a source 35 to the cooling block 24. The tubing 34 enters the cooling block 24 through an inlet 36 and has a bent, serpentine path through the cooling block 24 before exiting through an outlet 37. A pump 38 can be disposed in the cooling circuit to facilitate movement of the cooling fluid 42 from the source 35 through the tubing to the cooling block 24, and back to the source 35.

As shown in FIGS. 5 and 6, the cooling fluid source 35 can be a washer fluid reservoir 39. For example, a conventional cap for the washer fluid reservoir can be modified or replaced to accommodate the tubing 34. The pump 38 draws cooling fluid from the washer fluid reservoir 39 through a first end 40 of the tubing 34. After passing through the cooling block 24, the cooling fluid 42 is returned to the washer fluid reservoir 39 through a second end 41 of the tubing 34. To further decrease the temperature of the cooling fluid 42 supplied to the cooling block 24, a fan 43 can be mounted in the engine compartment to blow cool air 44 on the tubing 34 prior to entering the cooling block 24, as shown in FIG. 5. The washer fluid reservoir 39 can be the washer fluid reservoir for the front and/or rear windshield wipers and/or the headlamps. Alternatively, the washer fluid reservoir 39 can be a separate reservoir solely for supplying cooling fluid to the cooling block 24.

As shown in FIGS. 7 and 8, a second exemplary cooling circuit 15 is in fluid communication with an air conditioning system refrigerant loop 45 of the vehicle. The air conditioning system refrigerant loop 45 includes a compressor 46, a condenser 47, an expansion device 48, an evaporator 49 and a controller 50. The compressor 46 is configured to compress refrigerant. Operation of the compressor 46 is controlled by the controller 50, as described in greater detail below. The compressor 46 includes a conventional clutch or other similar mechanism such that the rotation of the engine 51 selectively powers the compressor 46.

The compressor 46 is preferably powered by the engine 51 in a conventional manner, but can alternatively be powered by an electric motor (not shown) separate from the engine 51. The compressor 46 is fluidly connected to the condenser 47 and the evaporator 49 by refrigerant tubing 52 in a conventional manner. The compressor 46 is configured to compress low pressure refrigerant received from the evaporator 49 and deliver high pressure refrigerant to the condenser 47.

The condenser 47 is fluidly coupled to the compressor 46 to receive the compressed refrigerant from the compressor 46 and dissipate heat therefrom in a conventional manner. The expansion device 48 is configured to throttle the refrigerant, allowing it to expand and thereby reducing pressure of the refrigerant as the refrigerant enters the evaporator 49. The evaporator 49 is fluidly coupled to the condenser 47 via the expansion device 48 to receive the expanded refrigerant from the condenser 47. The evaporator 49 is further configured to cool or absorb heat from air provided to the passenger compartment and is further fluidly coupled to the compressor 46 to supply the refrigerant to the compressor 46. The compressor 46, the condenser 47, the expansion device 48 and the evaporator 49 are preferably conventional devices fluidly connected to one another by conventional high and low pressure refrigerant lines. Consequently, description of these conventional devices is omitted for the sake of brevity.

The cooling circuit 15 is preferably connected to the refrigerant tubing 52 downstream of the evaporator 49 and upstream of the compressor 46, as shown in FIGS. 7 and 8. The cooling circuit tubing 34 is in fluid communication with the refrigerant tubing to supply the refrigerant as the cooling fluid to the cooling block 24 of the energy harvesting module 14. Fluidly connecting the cooling block 24 to the refrigerant loop 45 between the evaporator 49 and the compressor 46 supplies the coolest refrigerant to the cooling block 24. The energy harvesting module 14 can be connected to the exhaust piping 62 from the engine 51, as shown in FIG. 8. A large temperature differential is experienced at the thermoelectric device 22 of the energy harvesting module 14 between the high temperature heat of the exhaust piping 62 and the low temperature refrigerant supplied to the cooling block 24 from the refrigerant tubing 52. A pump 38 can be disposed in the cooling circuit 15 to facilitate moving the refrigerant through the cooling block 24 when the air conditioning system is not being operated. Additionally, a fan 43 can be used to further cool the refrigerant being supplied to the cooling block 24, as shown in FIG. 2. Alternatively, the cooling circuit tubing 34 can be connected to the refrigerant tubing 52 at any suitable location, such as upstream of the evaporator 49 and downstream of the expansion device 48 as shown in FIG. 8.

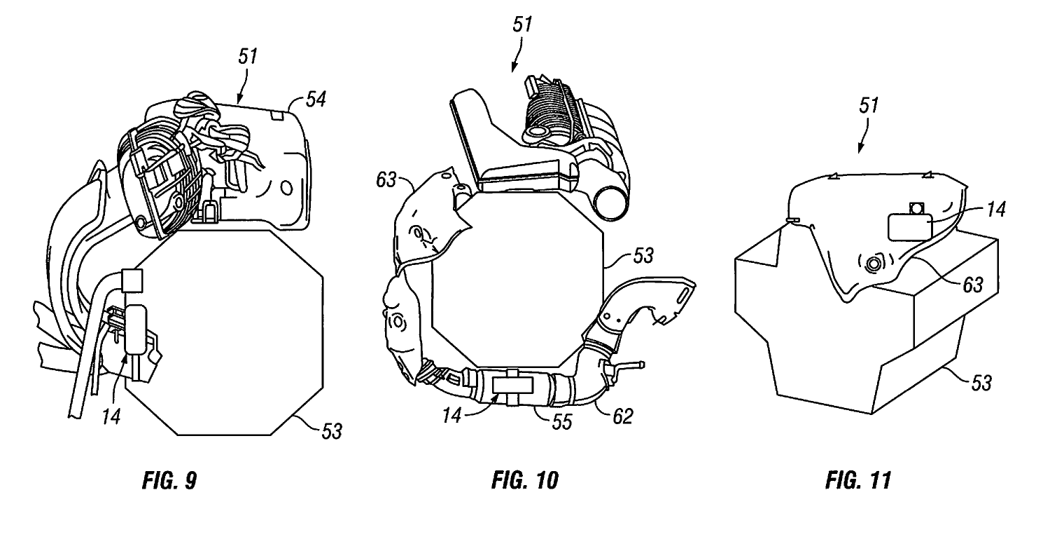

The energy harvesting module 14 can be secured to any suitable heat generating component 25 in the engine compartment of the vehicle, as shown in FIG. 3. Preferably, the energy harvesting module 14 is connected to a component of the engine block 53, as shown in FIGS. 9-11, to collect waste heat. The energy harvesting module 14 can be disposed adjacent to hot coolant lines exiting the engine 51 as shown in FIG. 9, mounted to the catalytic converter 55 in the exhaust piping of the exhaust system as shown in FIG. 10, or mounted to a heat shield 63 (or directly to a cylinder block 53 of the engine 51) as shown in FIG. 11.

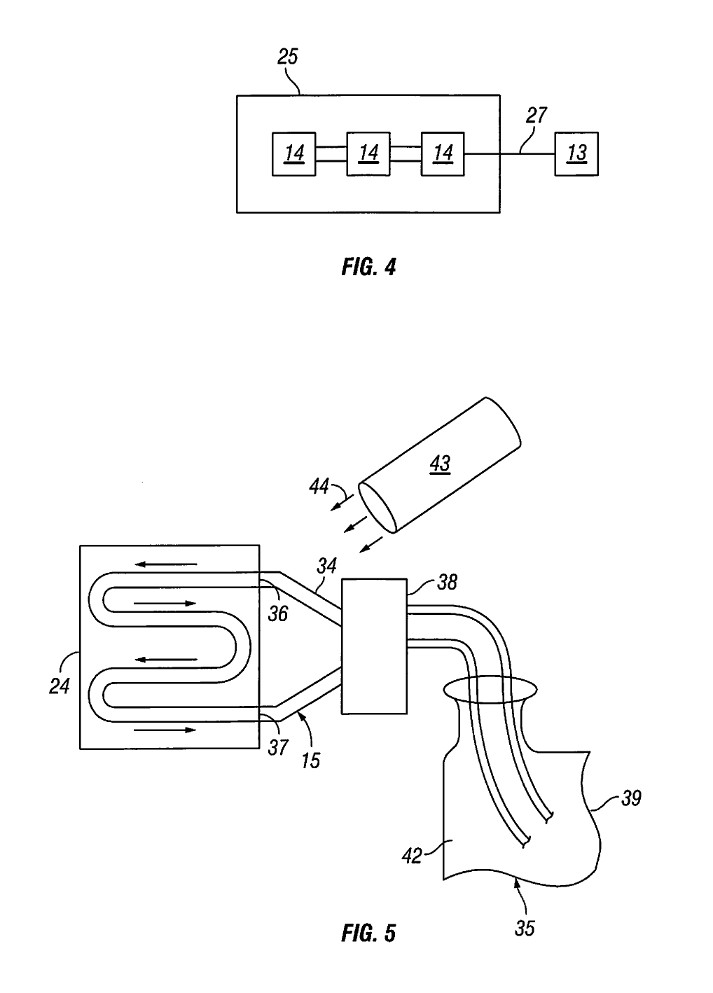

To increase the amount of electricity generated from the collected waste heat, a plurality of energy harvesting modules 14 can be mounted to the vehicle component 25 and electrically connected in series, as shown in FIG. 4. Alternatively, the energy harvesting modules 14 can be mounted to different vehicle components, with the energy harvesting modules 14 being electrically connected in series. The last energy harvesting module 14 in the series is connected to the charging module 13.

A solar harvesting module 56 can be electrically connected to the charging module 13, as shown in FIG. 2, to further increase the amount of electrical energy supplied to the charging module 13. The solar harvesting module 56 harvests solar power and converts the harvested solar power to electrical energy. A wire 57 supplies the electrical energy to the charging module 13. The solar harvesting module 56 can be disposed in any suitable location to collect solar power, such as a vehicle windshield.

An indicator light 58 can be disposed on the charging module 13, as shown in FIG. 1. The indicator light 58 is illuminated when the charging module 13 is collecting electrical energy from the energy harvesting module 14 and/or the solar harvesting module 56. In addition to or instead of indicator light 58, an indicator light can be mounted on an instrument panel of the vehicle to indicate to an occupant in the passenger compartment that the charging module 13 is collecting electrical energy.

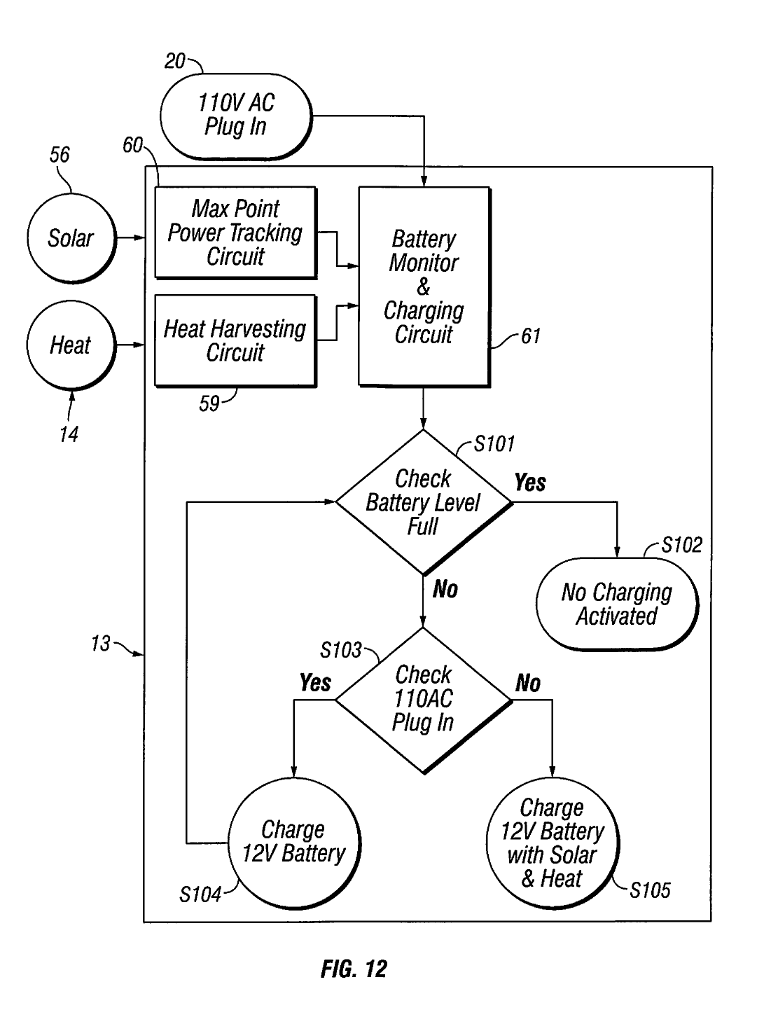

A method of charging a vehicle battery is shown in FIG. 12. Heat energy is captured with the energy harvesting module 14. As described above, the cooling fluid is supplied to the energy harvesting module 14 to increase a temperature difference at a thermoelectric device 22 (FIG. 3) of the energy harvesting module 14. The captured heat energy is converted to electrical energy with the energy harvesting module 14. The converted electrical energy is supplied to the charging module 13, which stores the electrical energy.

A solar harvesting module 56 captures solar power and converts the solar power to electrical energy. The converted electrical energy is supplied to the charging module 13, which stores the electrical energy.

The charging module 13 includes a heat harvesting circuit 59 that tracks the electrical power supplied from the energy harvesting module 56. A maximum point power tracking circuit 60 tracks the electrical power supplied from the solar harvesting module 56. A battery monitor and charging circuit 61 monitors the charge level of the vehicle battery 12. When the battery charge level falls below fully charged, the battery monitor and charging circuit 61 causes the electrical power to be supplied from the charging module 13 to the battery 12.

In step S101, the battery monitor and charging circuit determines the charge level of the battery 12. When the charge level is full, the battery 12 is not charged as shown in step S102. When the charge level is not full, the battery monitor and charging circuit checks whether an electrical connector is connected to the electrical socket 20 (FIG. 1) of the charging module 13 as shown in step S013. When the electrical connector is received, the battery 12 is charged with electrical power supplied from the electrical connector to the charging module 13 as shown in step S104. When an electrical connector is not detected at step S103, the battery 12 is charged with electrical power supplied from the energy harvesting module 14 and/or the solar harvesting module 56.

### GENERAL INTERPRETATION OF TERMS

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Also as used herein to describe the above embodiments, the following directional terms “forward”, “rearward”, “above”, “downward”, “vertical”, “horizontal”, “below” and “transverse” as well as any other similar directional terms refer to those directions of a vehicle.

The terms of degree such as “substantially”, “about” and “approximately” as used herein mean a reasonable amount of deviation of the modified term such that the end result is not significantly changed.

While only selected embodiments have been chosen to illustrate the present invention, it will be apparent to those skilled in the art from this disclosure that various changes and modifications can be made herein without departing from the scope of the invention as defined in the appended claims. For example, the size, shape, location or orientation of the various components can be changed as needed and/or desired. Components that are shown directly connected or contacting each other can have intermediate structures disposed between them. The functions of one element can be performed by two, and vice versa. The structures and functions of one embodiment can be adopted in another embodiment. It is not necessary for all advantages to be present in a particular embodiment at the same time. Every feature which is unique from the prior art, alone or in combination with other features, also should be considered a separate description of further inventions by the applicant, including the structural and/or functional concepts embodied by such features. Thus, the foregoing descriptions of the embodiments according to the present invention are provided for illustration only, and not for the purpose of limiting the invention as defined by the appended claims and their equivalents.

What is claimed is:

1. A battery charging assembly for a vehicle, comprising:
a battery;
a charging module electrically connected to the battery and configured to supply electrical energy to the battery;
an energy harvesting module electrically connected to the charging module, the energy harvesting module being configured to harvest energy, to convert the harvested energy to electrical energy and to supply the electrical energy to the charging module; and
a cooling circuit supplying a cooling fluid to the energy harvesting module to cool the energy harvesting module.

2. The battery charging assembly for a vehicle according to claim 1, wherein
the energy harvesting module is configured to convert harvested thermal energy to electrical energy and is disposed within an engine compartment of the vehicle.

3. The battery charging assembly for a vehicle according to claim 1, wherein
the charging module includes an electrical socket configured to receive an electrical connector to supply electrical energy thereto.

4. The battery charging assembly for a vehicle according to claim 1, wherein
a plurality of energy harvesting modules is connected in series with the charging module.

5. The battery charging assembly for a vehicle according to claim 1, wherein the energy harvesting module includes
a thermoelectric device configured to convert the harvested thermal energy to the electrical energy, the thermoelectric device having opposite first and second sides;
a heat sink connected to a first side of the thermoelectric device; and
a cooling block connected to the second side of the thermoelectric device.

6. The battery charging assembly for a vehicle according to claim 5, wherein the energy harvesting module includes
a thermal pad connected between the heat sink and a vehicle component disposed in an engine compartment of the vehicle.

7. The battery charging assembly for a vehicle according to claim 5, wherein
the cooling circuit includes a pump to move the cooling fluid through the cooling block.

8. The battery charging assembly for a vehicle according to claim 5, wherein
the cooling circuit is in fluid communication with an air conditioning system refrigerant loop of the vehicle.

9. The battery charging assembly for a vehicle according to claim 5, wherein
the cooling circuit is in fluid communication with a washer fluid reservoir.

10. The battery charging assembly for a vehicle according to claim 6, wherein
the thermal pad is connected to an engine block of the vehicle.

11. The battery charging assembly for a vehicle according to claim 1, wherein
an indicator light electrically connected to the energy harvesting module indicates when energy is being harvested, the indicator light being visible externally of the energy harvesting module.

12. A battery charging assembly for a vehicle, comprising:
a battery;
a charging module electrically connected to the battery and configured to supply electrical energy to the battery; and
an energy harvesting module disposed in an engine compartment of a vehicle and electrically connected to the charging module, the energy harvesting module being configured to harvest energy, to convert the harvested energy to electrical energy and to supply the electrical energy to the charging module, the energy harvesting module including
a thermoelectric device having opposite first and second sides;
a thermal pad configured to be connected to a vehicle component;
a heat sink connected between the thermal insulation pad and the first side of the thermoelectric device; and
a cooling block connected to a second side of the thermoelectric device; and
a cooling circuit supplying a cooling fluid to the cooling block of the energy harvesting module to cool the energy harvesting module.

13. The battery charging assembly for a vehicle according to claim 12, wherein
a plurality of energy harvesting modules is connected in series with the charging module.

14. The battery charging assembly for a vehicle according to claim 12, wherein
the charging module includes an electrical socket configured to receive an electrical connector to supply electrical energy thereto.

15. The battery charging assembly for a vehicle according to claim 12, wherein
the cooling circuit includes a pump to move the cooling fluid through the cooling block.

16. The battery charging assembly for a vehicle according to claim 12, wherein
the cooling circuit is in fluid communication with an air conditioning system refrigerant loop of the vehicle.

17. The battery charging assembly for a vehicle according to claim 12, wherein
the cooling circuit is in fluid communication with a washer fluid reservoir.

18. A method of charging a vehicle battery, comprising the steps of
capturing heat energy with an energy harvesting module;
supplying a cooling fluid to the energy harvesting module to increase a temperature difference at a thermoelectric device of the energy harvesting module;
converting the captured heat energy to electrical energy with the energy harvesting module;
storing the converted electrical energy; and
supplying the stored electrical energy to the battery when the battery is less than fully charged.

19. The method of charging a vehicle battery according to claim 18, wherein
the cooling fluid is supplied from an air conditioning system refrigerant loop of a vehicle.

20. The method of charging a vehicle battery according to claim 18, wherein
the cooling fluid is supplied from a washer fluid reservoir.
